(19) United States
(12) Patent Application Publication
(10) Pub. No.: US 2024/0258297 A1
(43) Pub. Date: Aug. 1, 2024

(54) ELECTRONIC DEVICE AND MANUFACTURING METHOD THEREOF

(71) Applicant: InnoLux Corporation, Miao-Li County (TW)

(72) Inventors: Kuang-Ming FAN, Miao-Li County (TW); Ju-Li Wang, Miao-Li County (TW); Chin-Ming Huang, Miao-Li County (TW); Sheng-Nan Chen, Miao-Li County (TW)

(73) Assignee: InnoLux Corporation, Miao-Li County (TW)

(21) Appl. No.: 18/409,824

(22) Filed: Jan. 11, 2024

Related U.S. Application Data
(60) Provisional application No. 63/442,119, filed on Jan. 31, 2023.

(30) Foreign Application Priority Data
Sep. 20, 2023 (CN) 202311210897.6

(51) Int. Cl. H01L 25/00; H01L 23/00; H01L 23/48; H01L 23/498; H01L 23/544; H01L 25/065

(52) U.S. Cl. CPC H01L 25/50; H01L 23/481; H01L 23/49816; H01L 23/49822; H01L 23/544; H01L 24/08; H01L 24/94; H01L 25/0655; H01L 2223/54426; H01L 2224/08225; H01L 2224/94; H01L 2924/181

(57) ABSTRACT

A manufacturing method of an electronic device and an electronic device are disclosed. The method includes: forming an intermediate layer on a first carrier, patterning the intermediate layer to form alignment marks; forming a release layer on the first carrier; disposing chips on the release layer, each chip including a bonding pad and a surface; forming an insulating layer surrounding the chips on the release layer to form a package structure; transferring the package structure to a second carrier, enabling the surface of each chip to face away from the second carrier and to be exposed by an upper surface of the insulating layer, a step difference formed between the surface of each chip and at least a portion of the upper surface of the insulating layer in a normal direction; and forming a redistribution layer electrically connected to each chip through the bonding pads on the package structure.

### CROSS REFERENCE TO RELATED APPLICATION

This application claims the benefit of U.S. Provisional Application No. 63/442,119, filed on Jan. 31, 2023. The content of the application is incorporated herein by reference.

### BACKGROUND OF THE DISCLOSURE

### 1. Field of the Disclosure

The present disclosure relates to a manufacturing method of an electronic device and a related electronic device, and more particularly to a manufacturing method of an electronic device for improving the alignment accuracy and an electronic device manufactured by the method.

### 2. Description of the Prior Art

Current manufacturing and production technology of some electronic devices often includes a process of packaging electronic elements or redistributing circuits. However, if misalignment occurred between the circuits and the electronic elements in an electronic device, it may cause electrical defect or abnormal reliability. Therefore, it is an important issue to improve the alignment accuracy between electronic elements of an electronic device or improve the alignment accuracy between electronic elements and the circuits.

### SUMMARY OF THE DISCLOSURE

One of objectives of the present disclosure is to provide a manufacturing method of an electronic device and a related electronic device, so as to solve the problems encountered by the conventional manufacturing methods of electronic devices, and the alignment accuracy may be improved and/or the cost may be reduced.

The present disclosure provides a manufacturing method of an electronic device. The method includes: forming an intermediate layer on a first carrier and patterning the intermediate layer to form a plurality of alignment marks; forming a release layer on the first carrier; disposing a plurality of chips on the release layer, wherein each of the chips includes a bonding pad and a surface adjacent to the bonding pad; forming an insulating layer on the release layer, wherein the insulating layer surrounds the chips, so that the insulating layer and the chips form a package structure; transferring the package structure to a second carrier and enabling the surface of each of the chips to face away from the second carrier and to be exposed by an upper surface of the insulating layer, wherein a step difference is formed between the surface of each of the chips and at least a portion of the upper surface of the insulating layer in a normal direction of the surface of each of the chips; and forming a redistribution layer on the package structure, wherein the redistribution layer is electrically connected to each of the chips through the bonding pads.

The present disclosure provides an electronic device. The electronic device includes a chip, an insulating layer and a redistribution unit. The chip includes a bonding pad and a surface adjacent to the bonding pad. The insulating layer surrounds the chip, and an upper surface of the insulating layer exposes the surface of the chip. The redistribution unit is disposed on the chip and the insulating layer and electrically connected to the chip through the bonding pad. A step difference exists between the surface of the chip and at least a portion of the upper surface of the insulating layer in a normal direction of the surface of the chip.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 is a flowchart of a manufacturing method of an electronic device according to an embodiment of the present disclosure.

FIG. 2A to FIG. 2F are schematic diagrams illustrating the process of a manufacturing method of an electronic device according to a first embodiment of the present disclosure.

FIG. 3 is a cross-sectional schematic diagram of an electronic device according to an embodiment of the present disclosure.

FIG. 4 is an enlarged cross-sectional schematic diagram of an alignment mark on a carrier according to an embodiment of the present disclosure.

FIG. 5A to FIG. 5B are schematic diagrams illustrating the process of a manufacturing method of an electronic device according to a second embodiment of the present disclosure.

FIG. 6A to FIG. 6C are schematic diagrams illustrating the process of a manufacturing method of an electronic device according to a third embodiment of the present disclosure.

FIG. 7 is a cross-sectional schematic diagram of an electronic device according to another embodiment of the present disclosure.

FIG. 8A to FIG. 8D are schematic diagrams illustrating the process of a manufacturing method of an electronic device according to a fourth embodiment of the present disclosure.

FIG. 9 is a cross-sectional schematic diagram of an electronic device according to still another embodiment of the present disclosure.

FIG. 10 is a cross-sectional schematic diagram of an electronic device according to a further embodiment of the present disclosure.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of the device, and certain components in various drawings may not be drawn to scale. In addition, the number and dimension of each component shown in drawings are only illustrative and are not intended to limit the scope of the present disclosure.

Certain terms are used throughout the description and following claims to refer to particular components. As one skilled in the art will understand, electronic equipment manufacturers may refer to a component by different names. This document does not intend to distinguish between components that differ in name but not function. In the following description and in the claims, the terms “include”, “comprise” and “have” are used in an open-ended fashion, and thus should be interpreted to mean “include, but not limited to . . . ”. When the terms “include”, “comprise” and/or “have” are used in the description of the present disclosure, the corresponding features, areas, steps, operations and/or components would be pointed to existence, but not limited to the existence or addition of one or a plurality of the corresponding or other features, areas, steps, operations, components and/or combinations thereof.

When an element or layer is referred to as being “on” or “connected to” another element or layer, it may be directly on or directly connected to the other element or layer, or intervening elements or layers may be presented (indirect condition). In contrast, when an element is referred to as being “directly on” or “directly connected to” another element or layer, there are no intervening elements or layers presented.

The directional terms mentioned in this document, such as “up”, “down”, “front”, “back”, “left”, “right”, etc., are only directions referring to the drawings. Therefore, the directional terms used are for illustration, not for limitation of the present disclosure.

The terms “about”, “equal”, “identical” or “the same”, and “substantially” or “approximately” mentioned in this document generally mean being within 20% of a given value or range, or being within 10%, 5%, 3%, 2%, 1% or 0.5% of a given value or range.

The ordinal numbers used in the description and claims, such as “first”, “second”, “third”, etc., are used to describe elements, but they do not mean and represent that the element(s) have any previous ordinal numbers, nor do they represent the order of one element and another element, or the order of manufacturing methods. The ordinal numbers are used only to clearly discriminate an element with a certain name from another element with the same name. The claims and the description may not use the same terms. Accordingly, in the following description, a first constituent element may be a second constituent element in a claim.

The electronic device of the present disclosure may be applied to a power module, a semiconductor package device, a display device, a light-emitting device, a backlight device, an antenna device, a sensing device or a tiled device, but not limited herein. The electronic device may include a bendable or flexible electronic device. The display device may include a non-self-emissive display device or a self-emissive display device. The antenna device may include a liquid-crystal type antenna device or an antenna device other than liquid-crystal type, and the sensing device may include a sensing device used for sensing capacitance, light, heat or ultrasonic waves, but not limited herein. The electronic device may include electronic elements such as passive elements and active elements, for example, capacitors, resistors, inductors, diodes, transistors, etc. The tiled device may be, for example, a display tiled device or an antenna tiled device, but not limited herein. It should be noted that the electronic device may be any arrangement and combination of the above, but not limited herein. The manufacturing process of the electronic device in the present disclosure may be applied to a wafer-level package (WLP) process or a panel-level package (PLP) process, and may be a chip-first process or a chip-last process, but not limited herein.

It should be noted that the technical features in different embodiments described in the following can be replaced, recombined, or mixed with one another to constitute another embodiment without departing from the spirit of the present disclosure.

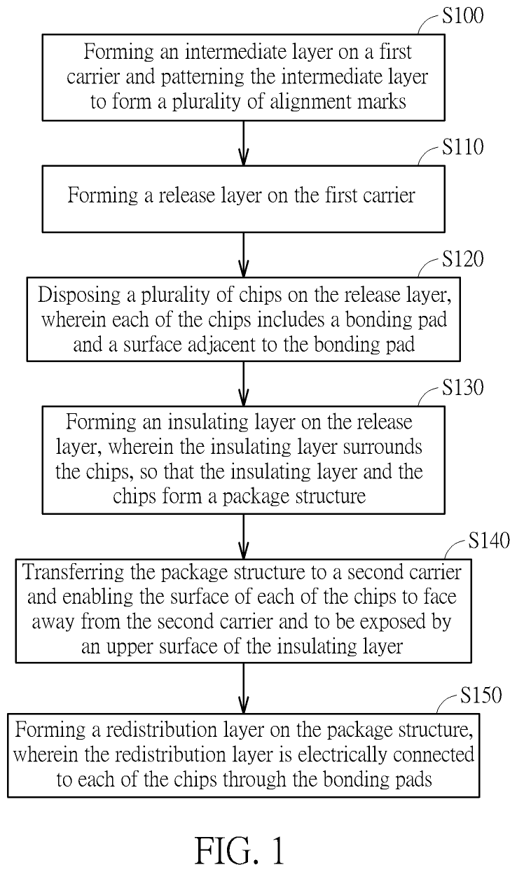

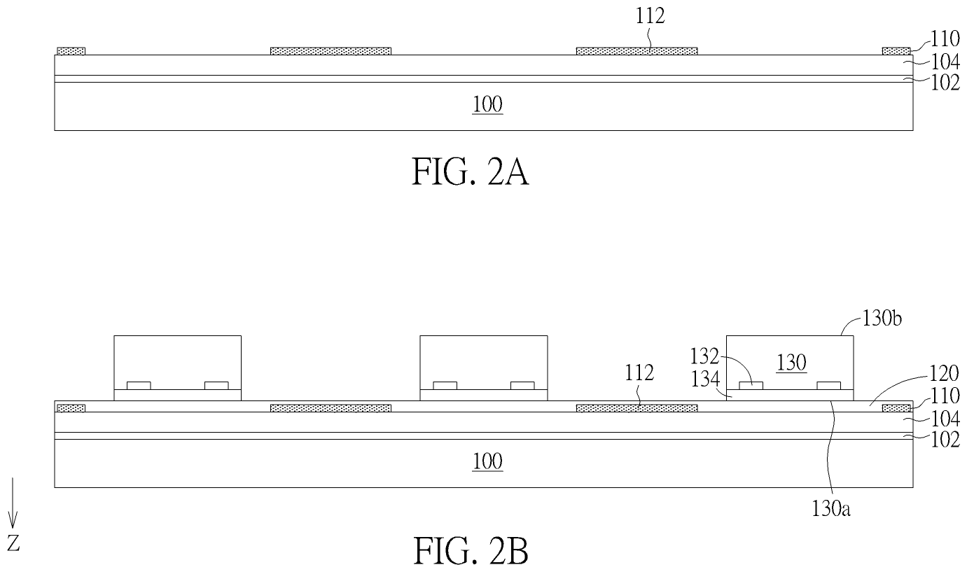

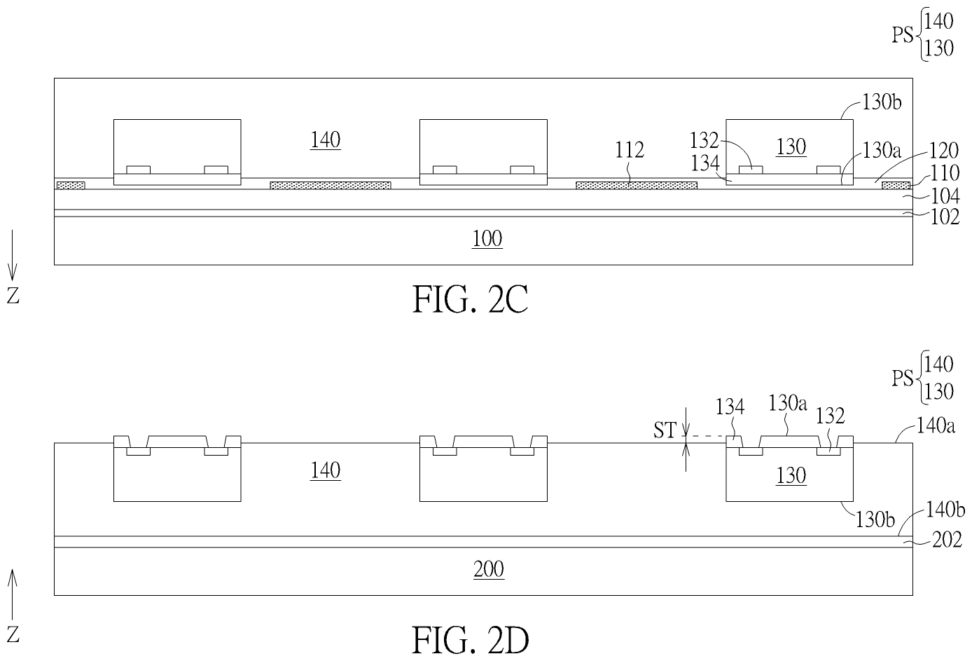

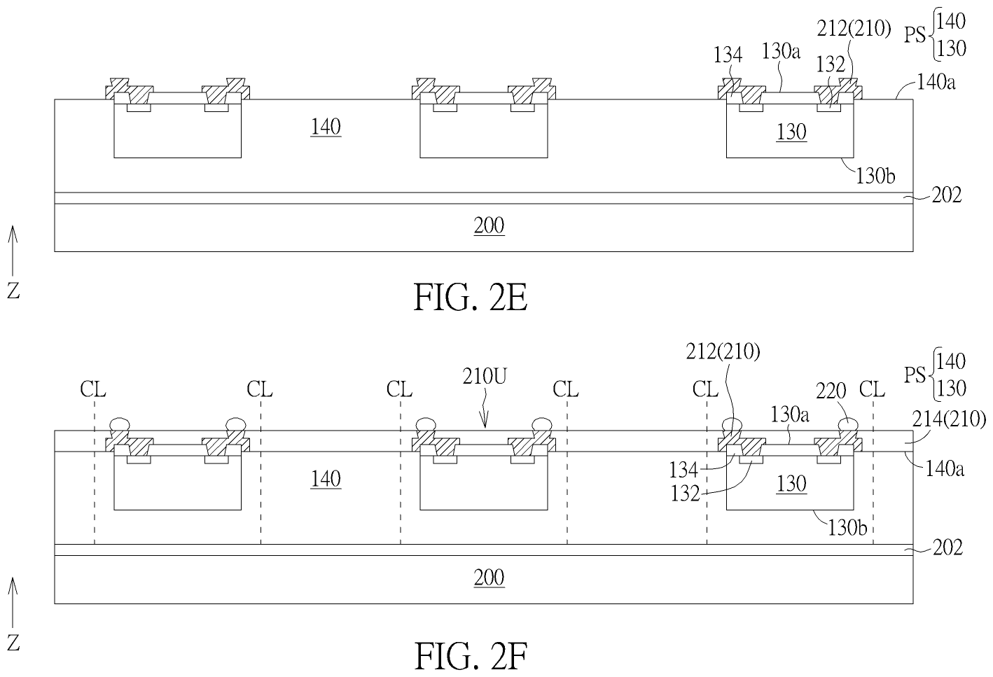

Please refer to FIG. 1 and FIG. 2A to FIG. 2F. FIG. 1 is a flowchart of a manufacturing method of an electronic device according to an embodiment of the present disclosure. FIG. 2A to FIG. 2F are schematic diagrams illustrating the process of a manufacturing method of an electronic device according to a first embodiment of the present disclosure. As shown in FIG. 1, a manufacturing method of an electronic device according to an embodiment of the present disclosure may include Step S100 to Step S150, as detailed in the following. According to a manufacturing method of an electronic device of a first embodiment of the present disclosure, as shown in FIG. 2A, first, Step S100 is performed to form an intermediate layer 110 on a first carrier 100 and pattern the intermediate layer 110 to form a plurality of alignment marks 112. The term “carrier” referred in the present disclosure may include a steel plate, glass, polyimide (PI), polyethylene terephthalate (PET), wafer, other suitable materials or combinations of the above materials. The intermediate layer 110 may include at least one of an organic material, an inorganic material, a metal material and a photoresist material, that is, the intermediate layer 110 may include one of the organic material, inorganic material, metal material and photoresist material or a composite material of a combination of the above materials. The photoresist material may include a positive photoresist material or a negative photoresist material. The intermediate layer 110 includes, for example, polymer, titanium, molybdenum, silicon oxide (SiOx), silicon nitride (SiNx), other suitable materials or combinations of the above materials, but not limited herein. In some embodiments, as shown in FIG. 2A, a release layer 102 and a light-transmitting substrate 104 may be optionally formed on the first carrier 100 before the step of forming the intermediate layer 110. That is to say, the intermediate layer 110 is formed on the light-transmitting substrate 104, and the light-transmitting substrate 104 may be disposed between the first carrier 100 and the patterned alignment marks 112. The light-transmitting substrate 104 is attached to the first carrier 100 through the release layer 102, which may increase the thickness of the whole structure, so as to reduce the possibility of causing warpage in the subsequent processes (such as a molding process). The light-transmitting substrate 104 may include glass or other suitable materials with high light transmittance, so that the alignment marks 112 formed on the surface of the light-transmitting substrate 104 may be identified more easily. The term “release layer” referred in the present disclosure may include an adhesive material, such as a glue material that can be dissociated or decomposed by laser, light or thermal, but not limited herein. The light-transmitting substrate or a substrate with high light transmittance referred in the present disclosure means that visible light, ultraviolet light and/or infrared light can pass through the substrate. For example, the transmittance of the substrate to a light source is at least greater than and or equal to 75%, wherein the transmittance may be measured by an optical apparatus.

Then, as shown in FIG. 2B, Step S110 may be performed to form a release layer 120 on the first carrier 100. Step S110 of forming the release layer 120 on the first carrier 100 may be performed after the step of forming the alignment marks 112, and the release layer 120 covers the alignment marks 112. For example, the release layer 120 may cover an upper surface and a side surface of the alignment mark 112. Then, Step S120 may be performed to dispose a plurality of chips 130 on the release layer 120, wherein each of the chips 130 includes a bonding pad 132 and a surface 130a adjacent to the bonding pad 132. Specifically, each of the chips 130 may have the surface 130a adjacent to the bonding pad 132 and another surface 130b away from the bonding pad 132 and opposite to the surface 130a, wherein the surface 130a of each of the chips 130 may contact the release layer 120. As shown in FIG. 2B, each of the chips 130 may include a plurality of (for example, two) bonding pads 132 and an insulating layer 134 covering the bonding pads 132, wherein a lower surface of the insulating layer 134 may be the surface 130a of the chip 130 contacting the release layer 120. The bonding pad 132 may include copper, aluminum, titanium, gallium, tantalum, other suitable materials or combinations of the above. The insulating layer 134 may include an organic material, inorganic material, dielectric material or other suitable insulating materials, such as (but not limited to) polyimide, epoxy, silicon nitride (SiNx), silicon oxide (SiOx) or combinations of the above. According to some embodiments, the chip 130 may have at least one insulating layer 134, that is, the chip 130 may include a single layer or multiple layers of insulating layer(s), and the insulating layer(s) may be used to protect the bonding pads 132 or reduce the probability of wafer breakage during cutting, but not limited herein. The chip 130 may include, for example, a diode or a semiconductor die, but is not limited herein. The diode may include a light-emitting diode or a photodiode. For example, the light-emitting diode may include an organic light-emitting diode (OLED), a mini light-emitting diode (mini LED), a micro light-emitting diode (micro LED) or a quantum dot light-emitting diode (quantum dot LED), but not limited herein. The chip 130 may be a known good die (KGD), which may include various electronic elements, such as (but not limited to) wires, transistors, etc. The adjacent chips 130 may have different functions from each other, such as being an integrated circuit, a radio frequency integrated circuit (RFIC), and a dynamic random access memory (D-RAM), but not limited herein.

According to the embodiments shown in FIG. 2B, Step S120 of disposing the chips 130 on the release layer 120 includes disposing each of the chips 130 between two adjacent ones of the alignment marks 112, that is, each of the chips 130 is not overlapped with the alignment mark 112 in a direction Z, wherein the direction Z may be parallel to a normal direction of the surface 130a of the chip 130 and perpendicular to the horizontal direction. The term “adjacent to” referred in the present disclosure may mean that an element A and an element B have a very small distance or a minimum distance therebetween in a direction, or may mean that there are no other identical elements between two identical elements in a direction.

Then, as shown in FIG. 2C, Step S130 may be performed to form an insulating layer 140 on the release layer 120, wherein the insulating layer 140 surrounds the chips 130, so that the insulating layer 140 and the chips 130 form a package structure PS. The term “surround” referred in the present disclosure may mean that in a cross-sectional view, the insulating layer 140 contacts at least one of the surfaces of the chip 130, such as the insulating layer 140 covering a side surface and/or the surface 130b of the chip 130. The insulating layer 140 may be used to isolate moisture and air and/or reduce the damage of the chip 130. The insulating layer 140 may include organic resin, epoxy, epoxy molding compound (EMC), ceramics, poly(methyl methacrylate) (PMMA), polydimethylsiloxane (PDMS), other suitable materials or combinations of the above materials, but not limited herein. The insulating layer 140 may include a filler, such as silicon oxide, but not limited herein. According to some embodiments, a particle size of the filler is greater than or equal to 0.05 micrometers (μm) and less than or equal to 30 micrometers (μm), or greater than or equal to 0.1 micrometers (μm) and less than or equal to 25 micrometers (μm). Each of the chips 130 may be subjected to pressure due to the packaging process when the insulating layer 140 is formed, so that a portion of each chip 130 sinks into the release layer 120, that is, as shown in FIG. 2C, the surface 130a on the bottom side of each chip 130 is lower than a surface on the bottom side of the insulating layer 140.

Then, as shown in FIG. 2D, Step S140 may be performed to transfer the package structure PS to a second carrier 200 and enable the surface 130a of each of the chips 130 to face away from the second carrier 200 and to be exposed by an upper surface 140a of the insulating layer 140. In the direction Z, a step difference ST is formed between the surface 130a of each of the chips 130 and at least a portion of the upper surface 140a of the insulating layer 140, wherein the step difference ST may be greater than or equal to 2 micrometers and less than or equal to 10 micrometers (i.e., 2 μm≤ST≤10 μm). If the step difference ST is out of the above range, the reliability of the package structure PS and the manufactured electronic device may be affected. For example, the structure formed in the subsequent processes on the package structure PS may be unstable when the step difference ST is too large, causing the conductive layer broken, for instance, thereby affecting the electrical properties; and it is difficult for a too-small step difference ST to enable the engaging and/or fixing between the layers in the structure formed in the subsequent process, but not limited herein. The plurality of step differences ST between the surface 130a of each chip 130 and the upper surface 140a of the insulating layer 140 are the height differences in the direction Z formed by pressing the chips 130 when forming the insulating layer 140 as described above. Specifically, as shown in FIG. 2D, in the direction Z, a first distance exists between the surface 130a of the chip 130 and a lower surface 140b of the insulating layer 140 opposite to the upper surface 140a, and a second distance exists between the upper surface 140a and the lower surface 140b of the insulating layer 140. A difference between the first distance and the second distance described above may be defined as the step difference ST, wherein the first distance may be greater than the second distance. In some embodiments, Step S140 of transferring the package structure PS to the second carrier 200 may include following steps. First, the second carrier 200 may be attached to a side of the package structure PS (e.g., a side of the package structure PS opposite to the first carrier 100) through a release layer 202. Then, the whole structure may be flipped upside-down, and the first carrier 100, the release layer 120 and the alignment marks 112 are removed. Then, the bonding pads 132 of the chips 130 are exposed. For example, holes may be formed in the insulating layer 134 of the chip 130 at the positions corresponding to the bonding pads 132 to expose the bonding pads 132, for example (but not limited to), forming the holes by patterning processes, such as etching. According to some embodiments, the holes may be formed in the insulating layers 134 of the chips 130 at the positions corresponding to the bonding pads 132 to expose the bonding pads 132, and then the chips 130 are disposed on the release layer 120. Then, the insulating layer 140 is disposed on the release layer 120, and the insulating layer 140 surrounds the plurality of chips 130, so that the insulating layer 140 and the chips 130 form the package structure PS. However, Step S140 of transferring the package structure PS to the second carrier 200 is not limited to the above. In other embodiments, the first carrier 100, the release layer 120 and the plurality of alignment marks 112 may be removed first, and then the package structure PS is flipped upside-down and attached to the second carrier 200 through the release layer 202.

Then, as shown in FIG. 2E and FIG. 2F, Step S150 may be performed to form a redistribution layer (RDL) 210 on the package structure PS, wherein the redistribution layer 210 is electrically connected to each of the chips 130 through the bonding pads 132. The redistribution layer 210 may include at least one conductive layer 212 and at least one insulating layer 214. The redistribution layer 210 may redistribute circuits and/or further increase the fan-out area of circuits, or different electronic elements may be electrically connected with each other through the redistribution layer 210. In some embodiments, the warpage of the structure may be restrained by a warpage reduction device before the redistribution layer 210 is formed, and then the redistribution layer 210 may be formed by processes such as (but not limited to) the thin-film deposition, acid etching, alkaline etching, surface treatment, plasma treatment, exposure and/or laser, but not limited herein. Specifically, as shown in FIG. 2E, a conductive layer 212 that is patterned may be formed on the insulating layer 140 and the insulating layer 134 of each chip 130, and the conductive layer 212 may be filled in the holes of the insulating layer 134 and electrically connected to the bonding pads 132 of each chip 130. The step differences ST (as shown in FIG. 2D) between the surface 130a of the chip 130 and the upper surface 140a of the insulating layer 140 may enable the effect that the boundary of the conductive layer 212, the insulating layer 134 and the insulating layer 140 are engaged and/or fixed, thereby improving the adhesion between the layers. Then, as shown in FIG. 2F, an insulating layer 214 may be formed on the conductive layer 212, thereby constituting the redistribution layer 210. The conductive layer 212 may include copper, aluminum, titanium, tantalum or other suitable conductive materials. The conductive layer 212 may be a single layer or a stack of multi-layers. The insulating layer 214 may include organic material, inorganic material, dielectric material or other suitable insulating materials, such as (but not limited to) polyimide, epoxy and/or silicon dioxide. Any two of the insulating layer 134, the insulating layer 140 and the insulating layer 214 may include the same or different materials, which may be selected according to the overall stress or the practical design. The redistribution layer 210 may include a plurality of redistribution units 210U, and each of the redistribution units 210U is electrically connected to at least one of the chips 130. A shown in FIG. 2F, a portion of the conductive layer 212 and a portion of the insulating layer 214 in the redistribution layer 210 may form a redistribution unit 210U, and each of the redistribution units 210U may correspond to and be electrically connected to one chip 130. The chip 130 may be electrically connected to at least one external element through the redistribution layer 210, wherein the external element may include another chip, a resistor, a capacitor, an inductor, an antenna unit, a sensing unit, a printed circuit board, a driving unit, combinations of the above or other suitable external elements or electronic units.

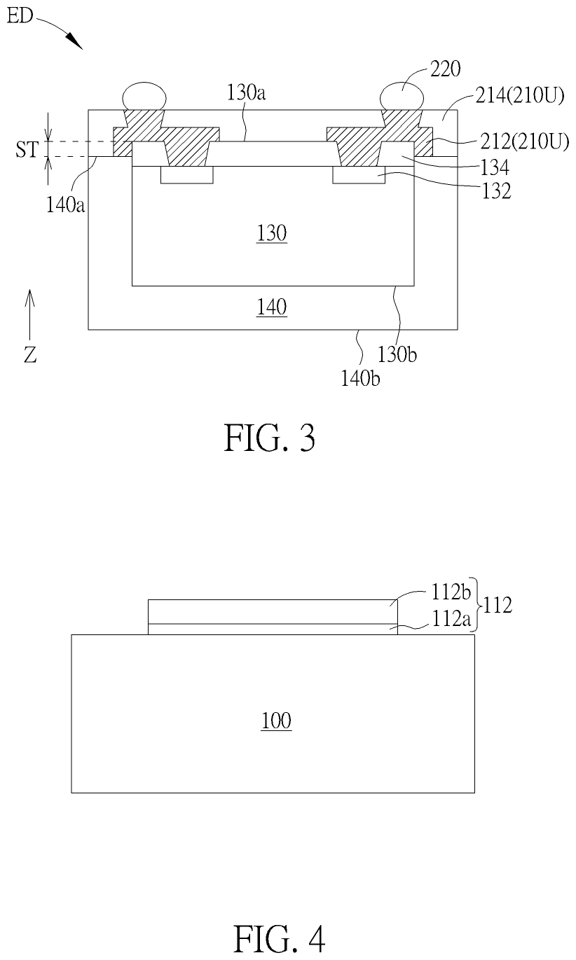

As shown in FIG. 2F, after Step S150 of forming the redistribution layer 210, a plurality of bonding elements 220 may further be formed on the redistribution layer 210, wherein the bonding elements 220 are electrically connected to the redistribution layer 210 individually. Specifically, the insulating layer 214 of the redistribution layer 210 may expose the surface of the conductive layer 212 located at the uppermost layer, and then the bonding elements 220 may be formed on the exposed conductive layer 212 in the redistribution layer 210, so that the bonding elements 220 may be electrically connected to the bonding pads 132 of each chip 130 through one of the redistribution units 210U, respectively. The bonding element 220 may be a bump, a pad, a solder ball or other suitable bonding elements. The bonding element 220 includes, for example, copper, tin, nickel, gold, lead, silver, gallium, other suitable conductive materials or combinations of the above materials, but not limited herein. After the plurality of bonding elements 220 are formed, the package structure PS may be cut along cutting lines CL, and then the second carrier 200 and the release layer 202 are removed, so that an electronic device ED including the chip 130 shown in FIG. 3 may be obtained.

Please refer to FIG. 3, which is a cross-sectional schematic diagram of an electronic device according to an embodiment of the present disclosure. As shown in FIG. 3, the electronic device ED manufactured by the method of the first embodiment includes the chip 130, the insulating layer 140 and the redistribution unit 210U. The chip 130 includes the bonding pad 132 and the surface 130a adjacent to the bonding pad 132. The insulating layer 140 surrounds the chip 130, and the upper surface 140a of the insulating layer 140 exposes the surface 130a of the chip 130. The redistribution unit 210U is disposed on the chip 130 and the insulating layer 140 and electrically connected to the chip 130 through the bonding pad 132. In the normal direction Z of the surface 130a of the chip 130, the step difference ST exists between the surface 130a of the chip 130 and at least a portion of the upper surface 140a of the insulating layer 140. The step difference ST may be greater than or equal to 2 micrometers and less than or equal to 10 micrometers (i.e., 2 μm≤ST≤10 μm). The electronic device ED may further include a plurality of bonding elements 220 disposed on and electrically connected to the conductive layer 212 exposed by the insulating layer 214 in the redistribution unit 210U. In some embodiments, the bonding elements 220 of the electronic device ED may be further electrically connected to a circuit board (not shown), but not limited herein.

According to the manufacturing method of the electronic device and the manufactured electronic device, the plurality of chips 130 may be disposed and aligned according to the plurality of alignment marks 112 during the manufacturing process, so that the alignment accuracy may be improved. Furthermore, the alignment marks 112 are formed by patterning the intermediate layer 110 formed on the carrier, wherein the manufacturing process of the alignment marks 112 is simple and the alignment marks 112 may be removed easily, so that the position of each of the alignment marks 112 may be defined more accurately, and the process cost may be reduced.

Please refer to FIG. 4, which is an enlarged cross-sectional schematic diagram of an alignment mark on a carrier according to an embodiment of the present disclosure. As shown in FIG. 4, an alignment mark 112 formed on the first carrier 100 may have a multi-layer structure including a first sub-layer 112a and a second sub-layer 112b, wherein the first sub-layer 112a and the second sub-layer 112b may include organic material, inorganic material, metal material, photoresist material or other suitable materials respectively, and the materials of the first sub-layer 112a and the second sub-layer 112b may be the same or different. The first sub-layer 112a is located between the second sub-layer 112b and the first carrier 100, which may improve the adhesion between the second sub-layer 112b and the first carrier 100. The first sub-layer 112a may further serve as a buffer layer. In other embodiments, the first sub-layer 112a may be a whole blanket layer and formed on the first carrier 100, but not limited herein.

Some embodiments of the manufacturing methods of the electronic devices and the manufactured electronic devices of the present disclosure will be detailed in the following. In order to simplify the illustration, the same elements in the following would be labeled with the same symbols. The differences between different embodiments are described in detail below, and the same features would not be described redundantly.

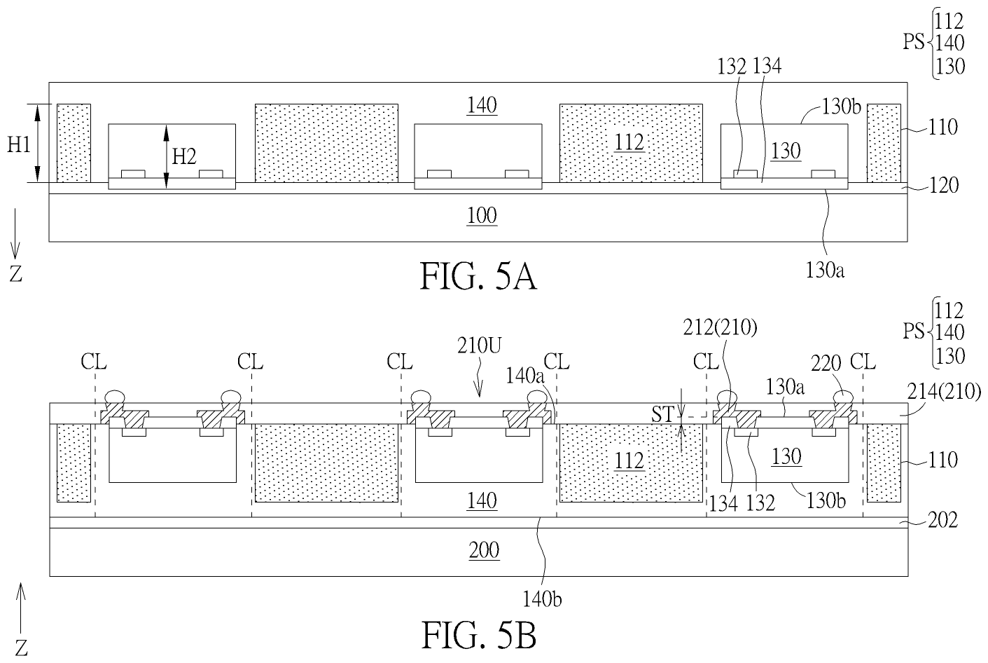

Please refer to FIG. 5A to FIG. 5B, accompanied with FIG. 1. FIG. 5A to FIG. 5B are schematic diagrams illustrating the process of a manufacturing method of an electronic device according to a second embodiment of the present disclosure. According to a manufacturing method of an electronic device of a second embodiment of the present disclosure, as shown in FIG. 5A, Step S110 of forming the release layer 120 on the first carrier 100 may be performed before the step of forming the intermediate layer 110. That is to say, the release layer 120 is formed on the first carrier 100 firstly, and then the intermediate layer 110 is formed on the release layer 120 and patterned to form a plurality of alignment marks 112. In the direction Z, a height H1 of each of the alignment marks 112 is greater than or equal to one third of a height H2 of at least one of the chips 130 to be disposed subsequently and less than or equal to five fourths of the height H2 of the at least one of the chips 130 (i.e., H2*⅓≤H1≤H2*5/4). For example, the chip 130 with the smallest height may be used as a reference or design basis when the heights of the chips 130 are different, but not limited herein. Then, Step S120 is performed to dispose a plurality of chips 130 on the release layer 120, wherein each of the chips 130 is disposed between two adjacent ones of the alignment marks 112. Through the height design of the alignment marks 112 described above, the positions of the chips 130 may be restricted, thereby reducing the position deviation of the chips 130. Then, Step S130 is performed to form the insulating layer 140 on the release layer 120, wherein the insulating layer 140 surrounds the chips 130 and the alignment marks 112, so as to form a package structure PS. Each of the chips 130 may be subjected to pressure due to the packaging process when the insulating layer 140 is formed, so that a portion of each chip 130 sinks into the release layer 120, thereby forming a plurality of step differences ST as shown in FIG. 5B.

Then as shown in FIG. 5B, Step S140 is performed to transfer the package structure PS to the second carrier 200, such as attaching the second carrier 200 to a side of the package structure PS through the release layer 202 and removing the first carrier 100 and the release layer 120. In the normal direction Z of the surface 130a of the chip 130, a step difference ST is formed between the surface 130a of each of the chips 130 and at least a portion of the upper surface 140a of the insulating layer 140. Then, Step S150 is performed to form the redistribution layer 210 including at least one conductive layer 212 and at least one insulating layer 214 on the package structure PS, and a plurality of bonding elements 220 are formed on the redistribution layer 210, so that the bonding elements 220 may be electrically connected to the bonding pads 132 of each chip 130 through one of the redistribution units 210U, respectively. Then, the package structure PS may be cut along the cutting lines CL, and then the second carrier 200 and the release layer 202 are removed, so that an electronic device ED including the chip 130 shown in FIG. 3 may be obtained.

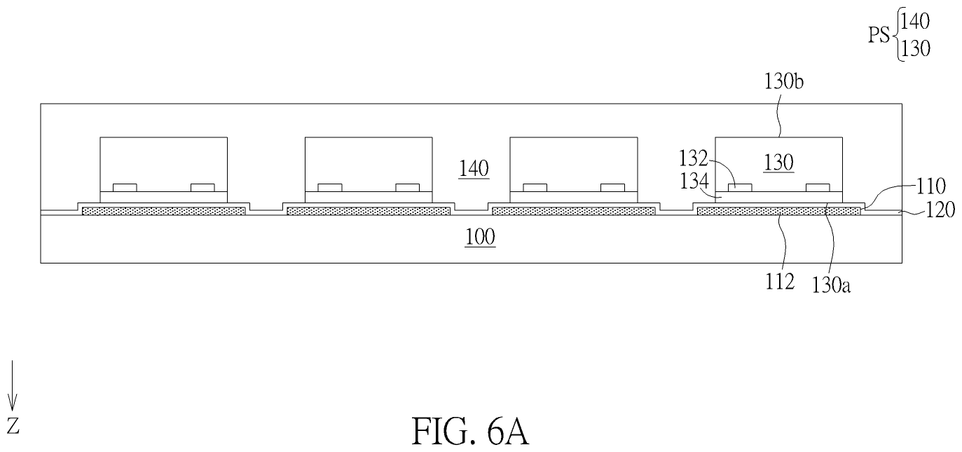

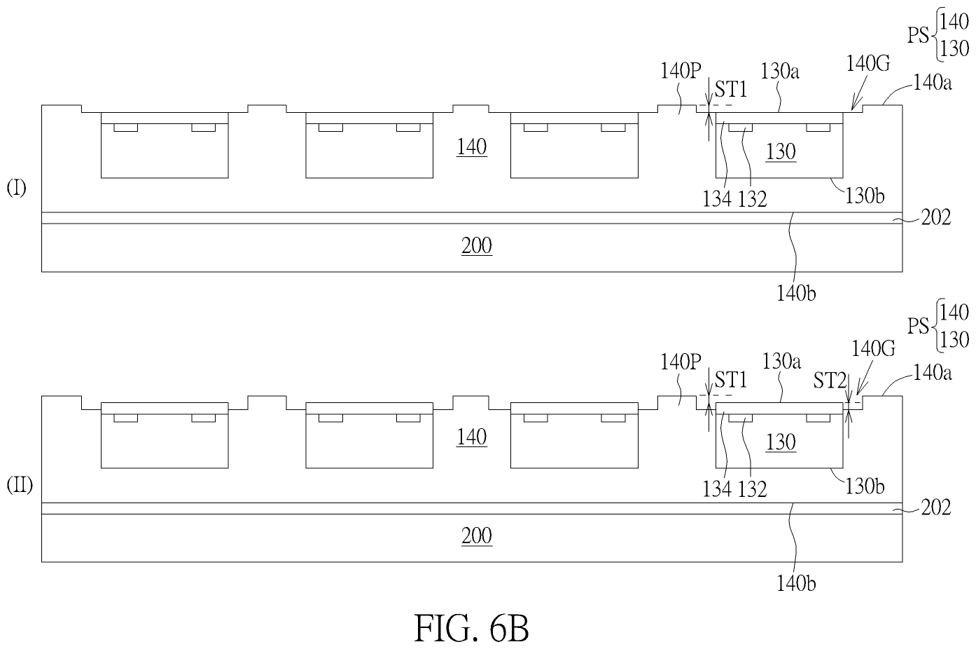

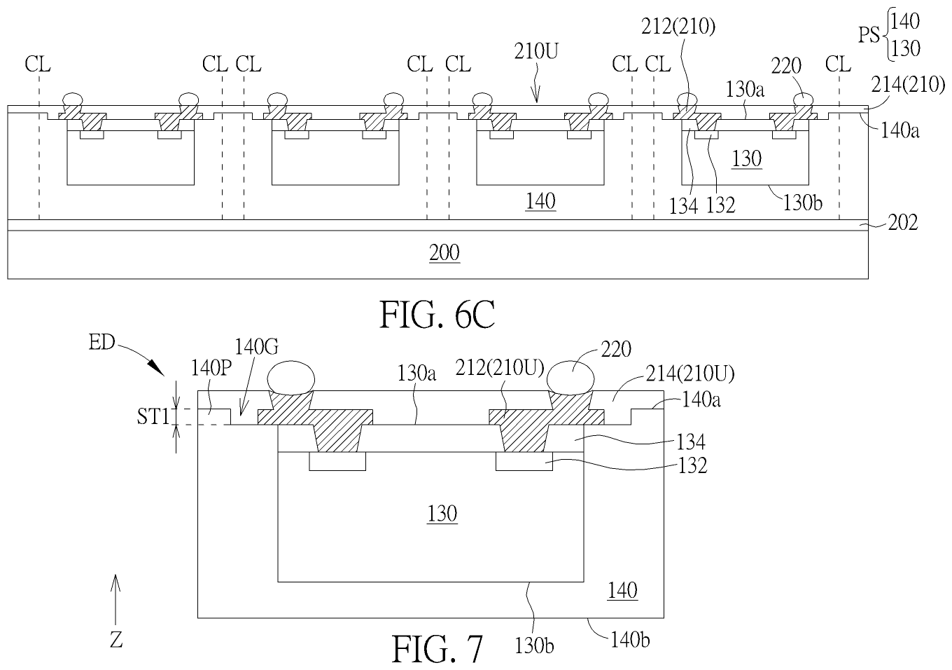

Please refer to FIG. 6A to FIG. 6C, accompanied with FIG. 1. FIG. 6A to FIG. 6C are schematic diagrams illustrating the process of a manufacturing method of an electronic device according to a third embodiment of the present disclosure. According to a manufacturing method of an electronic device of a third embodiment of the present disclosure, as shown in FIG. 6A, Step S110 of forming the release layer 120 on the first carrier 100 may be performed after the step of forming the alignment marks 112. That is to say, the intermediate layer 110 is formed on the first carrier 100 and patterned to form a plurality of alignment marks 112 firstly, and then the release layer 120 is formed on the first carrier 100 and the alignment marks 112, so that the release layer 120 covers the alignment marks 112 in a stepped manner conformed with the ups and downs of the alignment marks 112. Then, Step S120 is performed to dispose a plurality of chips 130 on the release layer 120, wherein each of the chips 130 is disposed on one of the alignment marks 112. In the normal direction Z of the surface 130a of the chip 130, the chip 130 may be overlapped with the alignment mark 112 one-to-one. Then, Step S130 is performed to form the insulating layer 140 on the release layer 120, wherein the insulating layer 140 surrounds the chips 130, so as to form a package structure PS.

Then, as shown in an example (I) or example (II) of FIG. 6B, Step S140 is performed to transfer the package structure PS to the second carrier 200, such as attaching the second carrier 200 to a side of the package structure PS through the release layer 202 and removing the first carrier 100, the release layer 120 and the alignment marks 112. The upper surface 140a of the insulating layer 140 may have a plurality of recess portions 140G, a protruding portion 140P may exist relatively at a side of the recess portion 140G and/or between two adjacent ones of the recess portions 140G, so that a step difference ST1 is formed between the surface 130a of each of the chips 130 and a portion of the upper surface 140a of the insulating layer 140 (such as a surface of the protruding portion 140P) in the direction Z. For example, the plurality of recess portions 140G are formed at the upper surface 140a of the insulating layer 140 after the alignment marks 112 are removed. The recess portions 140G and the protruding portions 140P may further serve as alignment marks, so that the subsequent process may be performed on the package structure PS in an alignment manner according to the recess portions 140G and/or the protruding portions 140P. Specifically, as shown in the example (I) or example (II) of FIG. 6B, in the direction Z, a first distance exists between the surface 130a of the chip 130 and the lower surface 140b of the insulating layer 140 opposite to the upper surface 140a, and a second distance exists between a portion of the upper surface 140a of the insulating layer 140 corresponding to the protruding portion 140P and the lower surface 140b of the insulating layer 140. A difference between the first distance and the second distance described above may be defined as the step difference ST1, wherein the second distance is greater than the first distance. In some embodiments, as shown in the example (I) of FIG. 6B, a portion of the upper surface 140a of the insulating layer 140 corresponding to the recess portion 140G may be aligned with the surface 130a of the chip 130. In some embodiments, as shown in the example (II) of FIG. 6B, a step difference ST2 may be further formed between the surface 130a of each of the chips 130 and the portion of the upper surface 140a of the insulating layer 140 corresponding to the recess portion 140G. Each of the chips 130 may be subjected to pressure due to the packaging process when the insulating layer 140 is formed, so that a portion of each chip 130 sinks into the release layer 120 (shown in FIG. 6A), thereby forming the step differences ST2. The step difference ST1 may range from 1.5 times of the step difference ST2 to twice the step difference ST2, which is beneficial to the engaging and/or fixing between the layers in the formed structure.

After the process shown in FIG. 6B, as shown in FIG. 6C, Step S150 is performed to form the redistribution layer 210 including at least one conductive layer 212 and at least one insulating layer 214 on the package structure PS, and a plurality of bonding elements 220 are formed on the redistribution layer 210, so that the bonding elements 220 may be electrically connected to the bonding pads 132 of each chip 130 through one of the redistribution units 210U, respectively. Then, the package structure PS may be cut along the cutting lines CL, and then the second carrier 200 and the release layer 202 are removed, so that an electronic device ED including the chip 130 shown in FIG. 7 may be obtained.

Please refer to FIG. 7, which is a cross-sectional schematic diagram of an electronic device according to another embodiment of the present disclosure. As shown in FIG. 7, the electronic device ED manufactured by the method of the third embodiment includes the chip 130, the insulating layer 140 and the redistribution unit 210U, and the detailed structure and included materials thereof may refer to the previous embodiments, which will not be described redundantly herein. In the normal direction Z of the surface 130a of the chip 130, the step difference ST1 exists between the surface 130a of the chip 130 and at least a portion of the upper surface 140a of the insulating layer 140 (such as the surface of the protruding portion 140P). The upper surface 140a of the insulating layer 140 has a recess portion 140G adjacent to the chip 130. A portion of the upper surface 140a of the insulating layer 140 corresponding to the recess portion 140G may be aligned with the surface 130a of the chip 130. The electronic device ED may further include a plurality of bonding elements 220 disposed on and electrically connected to the conductive layer 212 exposed by the insulating layer 214 in the redistribution unit 210U. One of the differences between FIG. 7 and FIG. 3 is that a surface of the conductive layer 212 exposed by the insulating layer 214 shown in FIG. 7 may be lower than the surface of the insulating layer 214, wherein this surface of the conductive layer 212 may be a concave surface, a concave surface having an arc-shape or a rough concave surface having an arc-shape. Specifically, the surface of the conductive layer 212 exposed by the insulating layer 214 may be a rough concave surface lower than the insulating layer 214 formed by a surface treatment, such as the acid etching, alkaline etching, laser, plasma, other suitable methods or combinations of the above. Through the above design, the connection strength between the conductive layer 212 and the bonding elements 220 may be improved, but not limited herein.

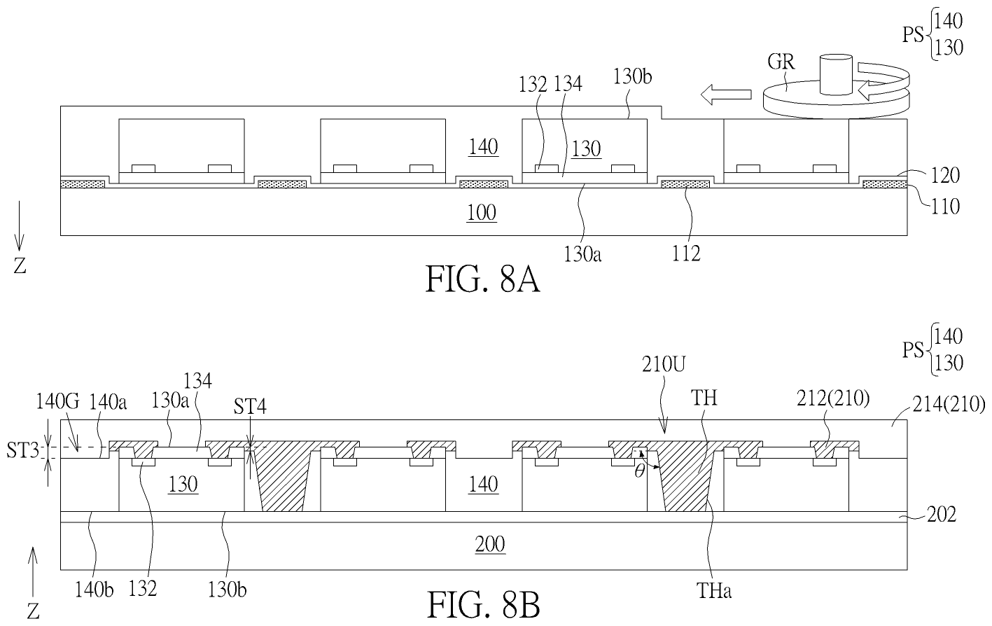

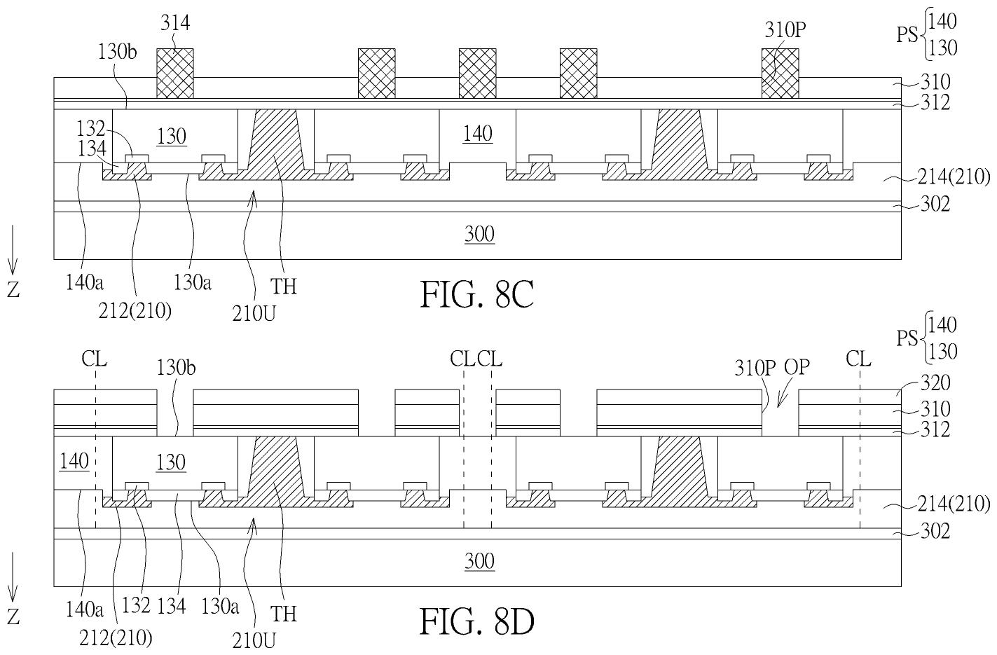

Please refer to FIG. 8A to FIG. 8D, accompanied with FIG. 1. FIG. 8A to FIG. 8D are schematic diagrams illustrating the process of a manufacturing method of an electronic device according to a fourth embodiment of the present disclosure. According to a manufacturing method of an electronic device of a fourth embodiment of the present disclosure, as shown in FIG. 8A, Step S110 of forming the release layer 120 on the first carrier 100 may be performed after the step of forming the alignment marks 112. That is to say, the intermediate layer 110 is formed on the first carrier 100 and patterned to form a plurality of alignment marks 112 firstly, and then the release layer 120 is formed on the first carrier 100 and the alignment marks 112, so that the release layer 120 covers the alignment marks 112 in a stepped manner conformed with the ups and downs of the alignment marks 112. Then, Step S120 is performed to dispose a plurality of chips 130 on the release layer 120, wherein each of the chips 130 is disposed between two adjacent ones of the alignment marks 112. Then, Step S130 is performed to form the insulating layer 140 on the release layer 120, wherein the insulating layer 140 surrounds the chips 130, so as to form a package structure PS. In some embodiments, after Step S130, a grinding process may be optionally performed by a grinding equipment GR as shown in FIG. 8A to remove a portion of the insulating layer 140 higher than the chips 130, so as to expose the surface 130b of each chip 130 far away from the bonding pad 132, but not limited herein.

After the process shown in FIG. 8A, as shown in FIG. 8B, Step S140 is performed to transfer the package structure PS to the second carrier 200, such as attaching the second carrier 200 to a side of the package structure PS through the release layer 202 and removing the first carrier 100, the release layer 120 and the alignment marks 112. A plurality of recess portions 140G are formed at the upper surface 140a of the insulating layer 140 after the alignment marks 112 are removed, so that a step difference ST3 is formed between the surface 130a of each of the chips 130 and a portion of the upper surface 140a of the insulating layer 140 (such as a surface of the recess portion 140G) in the direction Z. The recess portions 140G may further serve as alignment marks, so that the subsequent process may be performed on the package structure PS in an alignment manner according to the recess portions 140G. Specifically, as shown in FIG. 8B, in the direction Z, a first distance exists between the surface 130a of the chip 130 and the lower surface 140b of the insulating layer 140 opposite to the upper surface 140a, and a second distance exists between a portion of the upper surface 140a of the insulating layer 140 corresponding to the recess portion 140G and the lower surface 140b of the insulating layer 140. A difference between the first distance and the second distance described above may be defined as the step difference ST3, wherein the first distance is greater than the second distance. In some embodiments, as shown in FIG. 8B, a step difference ST4 may be further formed between the surface 130a of each of the chips 130 and a portion of the upper surface 140a of the insulating layer 140. Each of the chips 130 may be subjected to pressure due to the packaging process when the insulating layer 140 is formed, so that a portion of each chip 130 sinks into the release layer 120 (shown in FIG. 8A), thereby forming the step differences ST4.

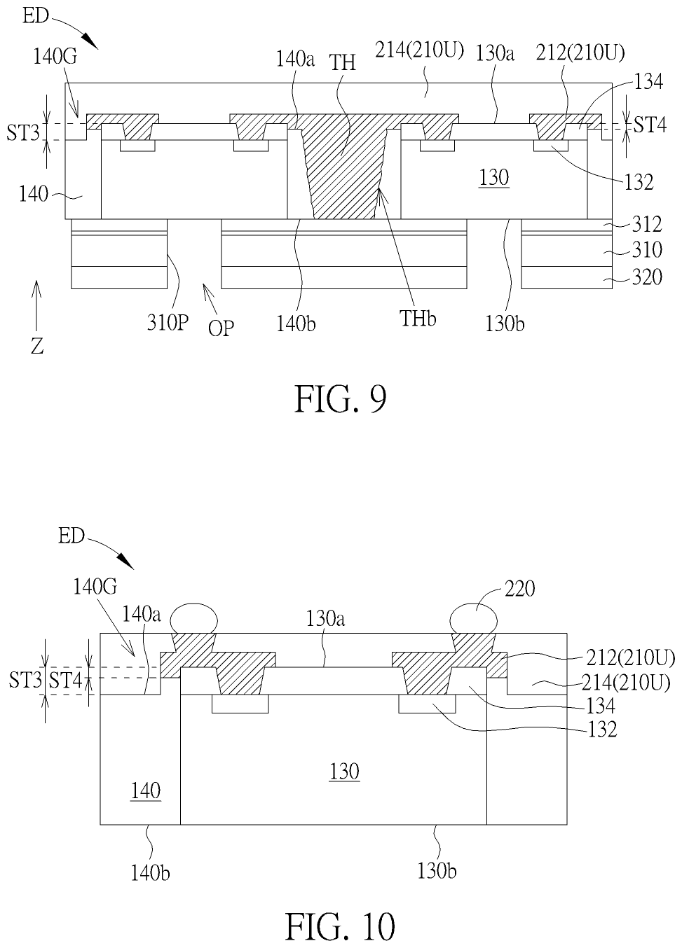

Then, Step S150 is performed to form the redistribution layer 210 including at least one conductive layer 212 and at least one insulating layer 214 on the package structure PS, and the conductive layer 212 of the redistribution layer 210 is electrically connected to each of the chips 130 through the bonding pads 132. The redistribution layer 210 may include a plurality of redistribution units 210U, and each of the redistribution units 210U may be electrically connected to two adjacent ones of the chips 130. The step differences ST4 between the surface 130a of the chip 130 and the upper surface 140a of the insulating layer 140 may enable the effect that the boundary of the conductive layer 212, the insulating layer 134 and the insulating layer 140 are engaged and/or fixed, thereby improving the adhesion between the layers. As shown in FIG. 8B, one or more through-hole structures TH are further formed when forming the redistribution layer 210. Each through-hole structure TH is located between two adjacent ones of the chips 130 and extends to pass through the insulating layer 140, and each through-hole structure TH is connected to one of the conductive layers 212 in the redistribution unit 210U, so that each through-hole structure TH is electrically connected to the two adjacent ones of the chips 130. For example, a through hole THa may be formed at a portion of the insulating layer 140 between the adjacent chips 130, and the position of the through hole THa may correspond to the position of one of the recess portions 140G formed after the alignment marks 112 are removed, and then a conductive material may be filled in the through hole THa to form the through-hole structure TH, wherein the conductive material may include, for example, copper, tin, nickel, gold, titanium, other suitable conductive materials or combinations of the above materials, but not limited herein. The conductive material filled in the through hole THa may be the same as the material of the conductive layer 212, or the conductive material filled in the through hole THa and the conductive layer 212 may be made of the same material. According to some embodiments, the through-hole structure TH may be hourglass-shaped, rectangular, trapezoidal, inverted trapezoidal or other suitable shapes. According to some embodiments, an included angle θ between a side wall THb of the through-hole structure TH and one surface of the insulating layer 214 may be greater than or equal to 95° and less than or equal to 150° (i.e., 95°≤θ≤150°), or the included angle θ may be greater than or equal to 105° and less than or equal to 135° (i.e., 105°≤θ≤135°). In addition, the roughness of the side wall THb of the through-hole structure TH may be greater than the roughness of the surface of the insulating layer 214, as shown in FIG. 9. Through the above design, the connection strength between the conductive material in the through-hole structure TH and the insulating layer 214 may be improved, and the risk of cracking may be reduced, thereby improving the reliability, but not limited herein.

Then, as shown in FIG. 8C, the package structure PS and the redistribution layer 210 may further be transferred to a third carrier 300. For example, the third carrier 300 may be attached to the insulating layer 214 of the redistribution layer 210 at a side of the package structure PS through a release layer 302, and the second carrier 200 and the release layer 202 may be removed. Then, a conductive layer 310 may be formed on a side of the package structure PS opposite to the redistribution layer 210, wherein the conductive layer 310 is electrically connected to the through-hole structure TH. For example, the conductive layer 310 may be formed by a process such as electroplating or chemical plating. The conductive layer 310 may include copper or other suitable conductive materials. A seed layer 312 may be formed on the side of the package structure PS opposite to the redistribution layer 210 before the conductive layer 310 is formed, wherein the seed layer 312 may be beneficial to the formation of the conductive layer 310 and/or improve the adhesion between the layers. The seed layer 312 may include material of a single-layer or multi-layers, such as including titanium, copper, molybdenum, aluminum, nickel, silver, tin, other suitable conductive materials or combinations of the above materials, but not limited herein. A plurality of photoresist patterns 314 may further be formed on the seed layer 312, and each of the photoresist patterns 314 may correspond to one of the chips 130 or be located between two adjacent ones of the chips 310. Then, the conductive layer 310 may be formed on the seed layer 312, and the photoresist patterns 314 may enable a plurality of openings 310P (shown in FIG. 8D) to be correspondingly formed in the conductive layer 310.

After the process shown in FIG. 8C, as shown in FIG. 8D, the conductive layer 310 may have a plurality of openings 310P after the photoresist patterns 314 are removed, thereby reducing the area of the conductive layer 310 and the stress, so as to reduce the warpage. Then, a bonding layer 320 may be formed on the conductive layer 310, so that the bonding layer 320 may be electrically connected to the through-hole structure TH through the conductive layer 310 and electrically connected to the bonding pads 132 of each of the chips 130 through the through-hole structure TH. The bonding layer 320 may include copper, tin, nickel, gold, lead, other suitable conductive materials or combinations of the above materials, but not limited herein. According to the embodiment shown in FIG. 8D, for example, the positions of the portions of the bonding layer 320 and the seed layer 312 corresponding to the openings 310P of the conductive layer 310 may be patterned to form a plurality of openings OP which are integrally communicated from the bonding layer 320 through the conductive layer 310 to the seed layer 312. Then, the package structure PS may be cut along the cutting lines CL, and then the third carrier 300 and the release layer 302 are removed, so that an electronic device ED including the chip 130 shown in FIG. 9 may be obtained.

Please refer to FIG. 9, which is a cross-sectional schematic diagram of an electronic device according to still another embodiment of the present disclosure. As shown in FIG. 9, the electronic device ED manufactured by the method of the fourth embodiment includes two chips 130, the insulating layer 140 and the redistribution unit 210U, and the detailed structure and included materials thereof may refer to the previous embodiments, which will not be described redundantly herein. The upper surface 140a of the insulating layer 140 may have the recess portion 140G adjacent to the chip 130. In the normal direction Z of the surface 130a of the chip 130, the step difference ST3 exists between a portion of the upper surface 140a of the insulating layer 140 corresponding to the recess portion 140G and the surface 130a of the chip 130. In addition, the step difference ST4 may further exist between the surface 130a of each of the chips 130 and another portion of the upper surface 140a of the insulating layer 140. The electronic device ED may further include the seed layer 312, the conductive layer 310, and the bonding layer 320 stacked on a side of the package structure PS opposite to the redistribution layer 210 in sequence, which are electrically connected to one of the conductive layers 212 in the redistribution unit 210U through the through-hole structure TH located between two adjacent chips 130 and extending through the insulating layer 140. In some embodiments, the bonding layer 320 of the electronic device ED may be further electrically connected to a circuit board (not shown), but not limited herein.

In some embodiments, after Step S140 as shown in FIG. 8B, that is, after transferring the package structure PS to the second carrier 200 and removing the alignment marks 112 to form a plurality of recess portions 140G, Step S150 of forming the redistribution layer 210 on the package structure PS as shown in FIG. 2E and FIG. 2F may be performed, and then a plurality of bonding elements 220 are formed on the redistribution layer 210, and the package structure PS is cut, so that an electronic device ED including the chip 130 shown in FIG. 10 may be obtained. Please refer to FIG. 10, which is a cross-sectional schematic diagram of an electronic device according to a further embodiment of the present disclosure. As shown in FIG. 10, the electronic device ED manufactured by the above method includes the chip 130, the insulating layer 140 and the redistribution unit 210U, and the detailed structure and included materials thereof may refer to the previous embodiments, which will not be described redundantly herein. The upper surface 140a of the insulating layer 140 may have the recess portion 140G adjacent to the chip 130. In the normal direction Z of the surface 130a of the chip 130, the step difference ST3 exists between a portion of the upper surface 140a of the insulating layer 140 corresponding to the recess portion 140G and the surface 130a of the chip 130. In addition, the step difference ST4 may further exist between the surface 130a of the chip 130 and another portion of the upper surface 140a of the insulating layer 140.

From the above description, according to the manufacturing methods of the electronic devices and the manufactured electronic devices of the embodiments of the present disclosure, the plurality of chips may be disposed in an alignment manner according to the plurality of alignment marks during the manufacturing process, so that the alignment accuracy may be improved. In addition, the alignment marks are formed by patterning the intermediate layer formed on the carrier, wherein the manufacturing process of the alignment marks is simple and the alignment marks may be removed easily, so that the process cost may be reduced. In addition, the step differences between the surface of the chip and the upper surface of the insulating layer may improve the adhesion between the layers and/or may be used for alignment. According to the manufacturing methods of the electronic devices provided by the present disclosure, the manufactured electronic devices have specific structural characteristics and may have higher yield and/or product reliability.

Those skilled in the art will readily observe that numerous modifications and alterations of the device and method may be made while retaining the teachings of the disclosure.

Accordingly, the above disclosure should be construed as limited only by the metes and bounds of the appended claims.

What is claimed is:

1. A manufacturing method of an electronic device, comprising:
forming an intermediate layer on a first carrier and patterning the intermediate layer to form a plurality of alignment marks;
forming a release layer on the first carrier;
disposing a plurality of chips on the release layer, wherein each of the chips comprises a bonding pad and a surface adjacent to the bonding pad;
forming an insulating layer on the release layer, wherein the insulating layer surrounds the chips, so that the insulating layer and the chips form a package structure;
transferring the package structure to a second carrier and enabling the surface of each of the chips to face away from the second carrier and to be exposed by an upper surface of the insulating layer, wherein a step difference is formed between the surface of each of the chips and at least a portion of the upper surface of the insulating layer in a normal direction of the surface of each of the chips; and
forming a redistribution layer on the package structure, wherein the redistribution layer is electrically connected to each of the chips through the bonding pads.

2. The manufacturing method of the electronic device according to claim 1, wherein the intermediate layer comprises at least one of an organic material, a metal material and a photoresist material.

3. The manufacturing method of the electronic device according to claim 1, wherein the step difference is greater than or equal to 2 micrometers and less than or equal to 10 micrometers.

4. The manufacturing method of the electronic device according to claim 1, wherein transferring the package structure to the second carrier comprises following steps:
attaching the second carrier to a side of the package structure;
removing the first carrier, the release layer and the alignment marks; and
exposing the bonding pads.

5. The manufacturing method of the electronic device according to claim 4, wherein the upper surface of the insulating layer has a plurality of recess portions.

6. The manufacturing method of the electronic device according to claim 1, wherein forming the release layer on the first carrier is performed after forming the alignment marks.

7. The manufacturing method of the electronic device according to claim 1, further comprising:
forming a light-transmitting substrate on the first carrier before forming the intermediate layer.

8. The manufacturing method of the electronic device according to claim 1, wherein forming the release layer on the first carrier is performed before forming the intermediate layer.

9. The manufacturing method of the electronic device according to claim 8, wherein a height of each of the alignment marks is greater than or equal to one third of a height of at least one of the chips and less than or equal to five fourths of the height of the at least one of the chips.

10. The manufacturing method of the electronic device according to claim 1, wherein disposing the chips on the release layer comprises disposing each of the chips between two adjacent ones of the alignment marks.

11. The manufacturing method of the electronic device according to claim 1, wherein disposing the chips on the release layer comprises disposing each of the chips on one of the alignment marks.

12. The manufacturing method of the electronic device according to claim 1, further comprising:
forming a plurality of bonding elements on the redistribution layer, wherein the bonding elements are electrically connected to the redistribution layer individually;
cutting the package structure; and
removing the second carrier.

13. The manufacturing method of the electronic device according to claim 1, wherein the redistribution layer comprises a plurality of redistribution units, and each of the redistribution units is electrically connected to at least one of the chips.

14. The manufacturing method of the electronic device according to claim 1, further comprising: forming a through-hole structure when forming the redistribution layer, wherein the through-hole structure is located between two adjacent ones of the chips and extends to pass through the insulating layer, and the through-hole structure is electrically connected to the two adjacent ones of the chips.

15. The manufacturing method of the electronic device according to claim 14, further comprising:
transferring the package structure and the redistribution layer to a third carrier; and
forming a conductive layer on a side of the package structure opposite to the redistribution layer, wherein the conductive layer is electrically connected to the through-hole structure.

16. The manufacturing method of the electronic device according to claim 15, wherein the conductive layer has a plurality of openings.

17. The manufacturing method of the electronic device according to claim 15, further comprising:
forming a bonding layer on the conductive layer; and
cutting the package structure.

18. An electronic device, comprising:
a chip comprising a bonding pad and a surface adjacent to the bonding pad;
an insulating layer surrounding the chip, wherein an upper surface of the insulating layer exposes the surface of the chip; and
a redistribution unit disposed on the chip and the insulating layer and electrically connected to the chip through the bonding pad,
wherein a step difference exists between the surface of the chip and at least a portion of the upper surface of the insulating layer in a normal direction of the surface of the chip.

19. The electronic device according to claim 18, wherein the step difference is greater than or equal to 2 micrometers and less than or equal to 10 micrometers.

20. The electronic device according to claim 18, wherein the upper surface of the insulating layer has a recess portion adjacent to the chip.
